(19) United States
(12) Patent Application Publication
(10) Pub. No.: US 2013/0057305 A1
(43) Pub. Date: Mar. 7, 2013

(54) HYBRID CONSTRUCTION MACHINE AND METHOD FOR MEASURING CAPACITANCE OF ELECTRICITY STORAGE DEVICE OF HYBRID CONSTRUCTION MACHINE

(71) Applicant: Shimon Jimbo, Oisomachi (JP)

(72) Inventor: Shimon Jimbo, Oisomachi (JP)

(73) Assignee: Komatsu Ltd., Tokyo (JP)

(21) Appl. No.: 13/583,985

(22) PCT Filed: May 13, 2011
(86) PCT No.: PCT/JP2011/061090

§ 371 Date: Nov. 20, 2012

(30) Foreign Application Priority Data
May 20, 2010 (JP) 2010-116803

(51) Int. Cl. G01R 31/36

(52) U.S. Cl. 324/750.01

(57) ABSTRACT

A hybrid construction machine includes: a measurement unit configured to measure a capacitance of an electricity storage device; and a monitoring unit configured to monitor a first condition in which an engine is driven, a second condition in which an adjustment value of a fuel adjusting unit adjusting an amount of fuel supplied to the engine is a predetermined value, and a third condition in which an operation unit and/or an upper swing body are locked and transmit a control signal for starting a measurement of the capacitance of the electricity storage device to the measurement unit when all conditions of the first to third conditions are satisfied.

### FIELD

The present invention relates to a hybrid construction machine including an engine, a generator motor, and an electricity storage device and capable of measuring a capacitance of the electricity storage device and a method of measuring a capacitance of an electricity storage device of a hybrid construction machine.

### BACKGROUND

In the field of a recent construction machine, a hybrid vehicle has been developed as in a general automobile. This kind of hybrid construction machine is equipped with an engine, a generator motor, an electricity storage device, and an operation unit. As the electricity storage device, a capacitor may be used. The capacitor is an electricity storage device capable of freely conducting charging and discharging, and accumulates electrical power generated when the generator motor is operated to generate electrical power. Further, the capacitor supplies the electrical power accumulated in the capacitor to a generator motor or an electric motor installed to drive an operation unit or an upper swing body through a driver such as an inverter.

When the capacitor is used for a long period of time or repeats over-charging or over-discharging, degradation in performance may gradually occur due to heat or the like. When the degradation in performance of the capacitor gradually occurs, the operation capability of the hybrid construction machine is degraded due to a decrease in the amount of the electrical power supplied to the electric motor. For this reason, when the degradation in performance gradually occurs after examining the performance degradation state of the capacitor, maintenance such as a replacement of the capacitor is performed.

Patent Literature 1 discloses a configuration in which degradation in the performance of a capacitor is determined by calculating the capacitance of the capacitor using a system mounted on a hybrid construction machine instead of an external device while an electricity storage device such as a capacitor is installed in a vehicle.

### CITATION LIST

### Patent Literature

Patent Literature 1: International Patent Publication Pamphlet No. WO 2009/116495

### SUMMARY

### Technical Problem

Here, in Patent Literature 1 described above, a technique is disclosed in which degradation in performance is determined by measuring the capacitance of the capacitor while driving a generator motor at a predetermined engine speed and a predetermined torque during the measurement of the capacitance of the capacitor. However, there has been a demand for further accurately measuring the capacitance of the capacitor.

The invention is made in view of the above-described circumstances, and it is an object to provide a hybrid construction machine capable of further accurately measuring a capacitance of an electricity storage device such as a capacitor and a method of measuring a capacitance of an electricity storage device of a hybrid construction machine.

### Solution to Problem

To overcome the problems and achieve the object, according to the present invention, a hybrid construction machine comprises: a measurement unit configured to measure a capacitance of an electricity storage device; and a monitoring unit configured to monitor a first condition in which an engine is driven, a second condition in which an adjustment value of a fuel adjusting unit adjusting an amount of fuel supplied to the engine is a predetermined value, and a third condition in which an operation unit and/or an upper swing body are locked and transmit a control signal for starting a measurement of the capacitance of the electricity storage device to the measurement unit when all conditions of the first to third conditions are satisfied.

According to the present invention, in the second condition, the adjustment value of the fuel adjusting unit is a maximum value in a adjustable range.

According to the present invention, the monitoring unit is configured to set a fourth condition in which an operation mode of controlling an engine speed of the engine and a pump absorption torque of a hydraulic pump at a constant state is set, and when all conditions of the first to fourth conditions are satisfied, the monitoring unit is configured to transmit the control signal for starting the measurement of the capacitance of the electricity storage device to the measurement unit.

According to the present invention, the monitoring unit is configured to generate a control signal for stopping the measurement of the capacitance of the electricity storage device when at least one condition of the first to fourth conditions is not satisfied during the measurement of the capacitance of the electricity storage device.

According to the present invention, the hybrid construction machine, further comprises: a display unit configured to perform a display and an instruction related to at least the measurement of the capacitance of the electricity storage device; and a display control unit configured to control the display unit to perform a guide display related to at least the measurement of the capacitance of the electricity storage device.

According to the present invention, the display control unit is configured to switch a screen of the display unit to a screen for instructing a start of the measurement of the capacitance of the electricity storage device when all conditions of the first to fourth conditions are satisfied.

According to the present invention, the display control unit is configured to display a progress state of the measurement of the capacitance of the electricity storage device when the measurement unit measures the capacitance of the electricity storage device.

According to the present invention, the measurement unit is configured to perform the measurement of the capacitance of the electricity storage device on a condition that a charge releasing process of the electricity storage device is performed.

According to the present invention, a method of measuring a capacitance of an electricity storage device of a hybrid construction machine comprises: monitoring a first condition in which an engine is driven, a second condition in which an adjustment value of a fuel adjusting unit adjusting an amount of fuel supplied to the engine is a predetermined value, and a third condition in which an operation unit and/or an upper swing body are locked to transmit a control signal for starting a measurement of the capacitance of the electricity storage device when all conditions of the first to third conditions are satisfied; and measuring the capacitance of the electricity storage device when the control signal for starting the measurement of the capacitance of the electricity storage device is received.

According to the present invention, the monitoring includes setting a fourth condition in which an operation mode of controlling an engine speed of the engine and a pump absorption torque of a hydraulic pump at a constant state and transmitting the control signal for starting the measurement of the capacitance of the electricity storage device when all conditions of the first to fourth conditions are satisfied.

### Advantageous Effects of Invention

According to the invention, since the monitoring unit monitors the first condition in which the engine is driven, the second condition in which the adjustment value of the fuel adjusting unit adjusting the amount of the fuel supplied to the engine is a predetermined value, and the third condition in which the operation unit and/or the upper swing body are locked and transmits the control signal for starting the measurement of the capacitance of the electricity storage device to the measurement unit when all conditions of first to third conditions are satisfied, the engine is driven at the maximum output state. Accordingly, the generator motor is also driven at a high rotation rate, so that the generated output is stable. Further, since the lock lever is locked, it is possible to prevent an unstable measurement of the capacitance due to the operation of the operation unit and hence further accurately measure the capacitance of the electricity storage device. Furthermore, since the generator motor is driven at a high rotation rate, the charging time to the electricity storage device is shortened, and hence the capacitance of the electricity storage device may be measured in a short time.

### BRIEF DESCRIPTION OF DRAWINGS

FIG. 1 is a diagram illustrating an external configuration of a hybrid construction machine as an embodiment of the invention.

FIG. 2 is a diagram illustrating an external configuration of a driver seat of the hybrid construction machine illustrated in FIG. 1.

FIG. 3 is a block diagram illustrating an internal configuration of the hybrid construction machine illustrated in FIG. 1.

FIG. 4 is a block diagram illustrating a configuration of a device concerned with a measurement of a capacitance of a capacitor.

FIG. 5 is a diagram illustrating an example of an operation mode selection screen which is displayed on a display screen of a monitor.

FIG. 6 is a flowchart illustrating a procedure of a display control process by a display control unit.

FIG. 7 is a diagram illustrating a display state transition of a monitor screen.

FIG. 8 is a flowchart illustrating a procedure of a monitoring process by a monitoring unit.

FIG. 9 is a flowchart illustrating a procedure of a process of measuring a capacitance of a capacitor by a measurement unit.

### DESCRIPTION OF EMBODIMENTS

Hereinafter, referring to the drawings, a hybrid construction machine of which a capacitance of an electricity storage device may be measured as an embodiment of the invention will be described. Furthermore, the invention is not limited to the embodiment.

### Entire Configuration

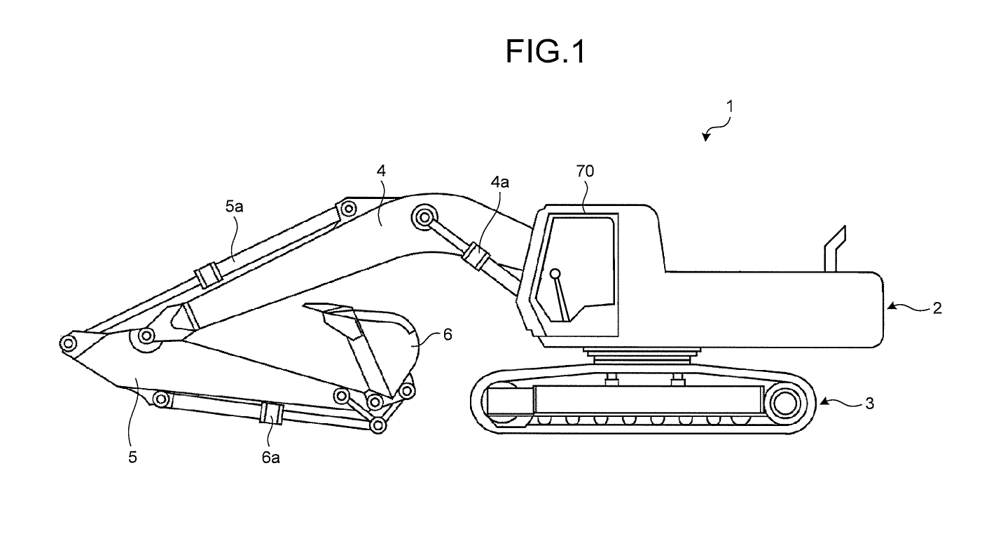

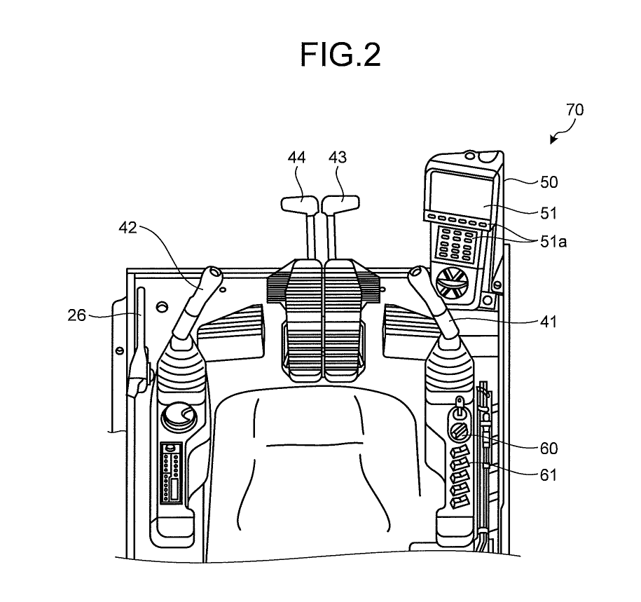

FIG. 1 is a diagram illustrating an external configuration of a hybrid construction machine 1 as an embodiment of the invention. Further, FIG. 2 is a diagram illustrating an external configuration of a driver seat 70 illustrated in FIG. 1. Furthermore, the hybrid construction machine 1 is an excavator.

In FIGS. 1 and 2, the hybrid construction machine 1 includes an upper swing body 2 and a lower traveling body 3, and the lower traveling body 3 includes left and right crawler tracks. An operation unit including a boom 4, an arm 5, and a bucket 6 is mounted on the upper swing body 2. The boom 4 is operated by driving a boom cylinder 4a, the arm 5 is operated by driving an arm cylinder 5a, and the bucket 6 is operated by driving a bucket cylinder 6a. Furthermore, a hook for hoisting a cargo is attached to a pin of a link which connects the bucket 6 and the arm 5 to each other in a case of the specification in which the hybrid construction machine 1 performs a cargo hoisting operation. Further, the lower traveling body 3 includes traveling motors 8 and 9, and the right crawler track and the left crawler track respectively rotate by the respective driving states thereof. When a swing machinery 114 is driven by electrically driving a swing motor 113 through a swing controller 112, the upper swing body 2 swings through a swing pinion, a swing circle, and the like.

An engine 12 is a diesel engine, and the control of the output (horsepower; kw) is performed by adjusting the amount of fuel injected into a cylinder. This adjustment is performed by controlling a governor attached to a fuel injection pump of the engine 12, and an engine controller 14 performs the control of the engine including the control of the governor. Furthermore, a throttle dial 60 is a fuel adjusting dial which serves as a fuel adjusting unit that defines the fuel injection amount. Furthermore, the throttle dial 60 is not limited to the dial type, and may be a manual type such as a lever type or a button type.

As illustrated in FIG. 2, a right operation lever 41 for operating an operation unit and a left operation lever 42 for swing the operation unit are respectively installed on the right side and the left side in front of the driver seat 70 of the hybrid construction machine 1, and a right operation lever 43 for operating a traveling operation and a left operation lever 44 for operating a traveling operation are respectively installed. Further, a lock lever 26 is installed at the left end of the driver seat 70.

The right operation lever 43 which operates the traveling operation and the left operation lever 44 which operates the traveling operation are operation levers for respectively operating the right crawler track and the left crawler track. The operation levers operate the crawler tracks in response to the operation directions and operate the crawler tracks at a speed corresponding to the operation amount.

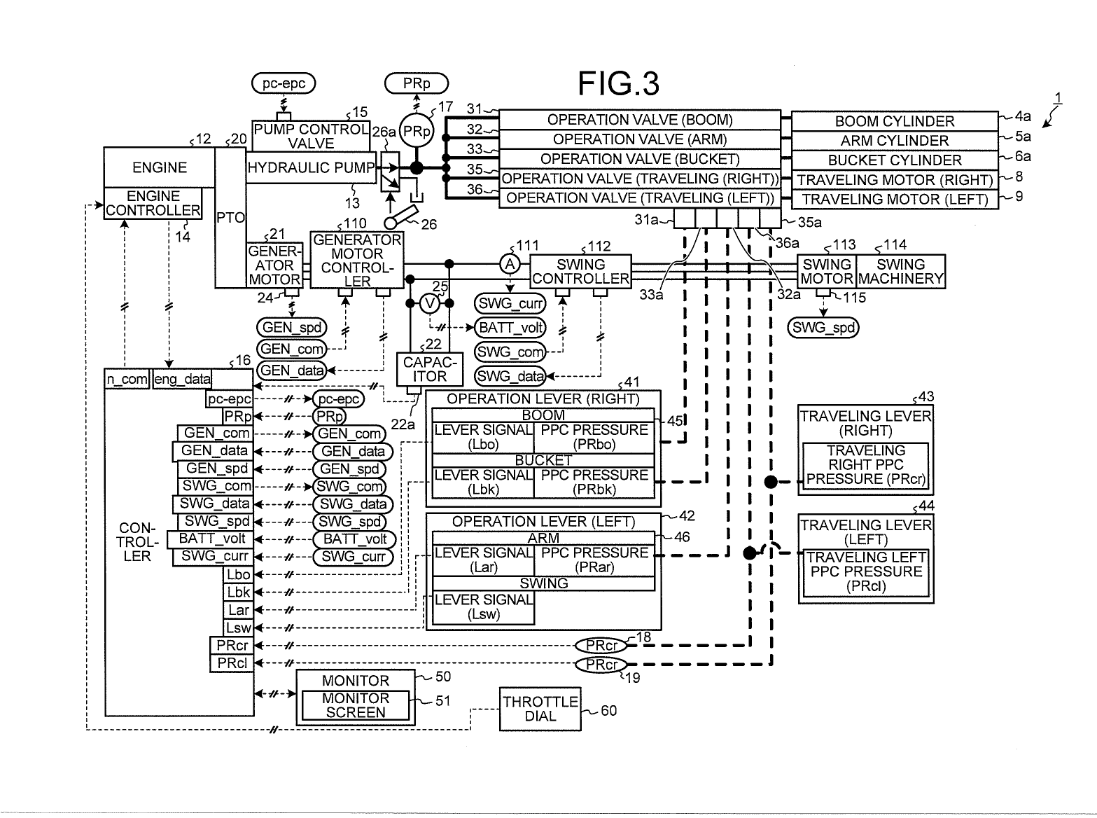

Further, as illustrated in FIG. 2, a monitor 50 is installed at the corner of the front right side of the driver seat 70. The monitor 50 is electrically connected to a controller 16 illustrated in FIG. 3, and includes a monitor screen 51. The monitor 50 is a display device which displays various information items on the monitor screen 51 and through which various operation instructions and the like are input to the hybrid construction machine 1.

The monitor 50 is provided with an operation button 51a. The operation button 51a includes a plurality of operation buttons, and when the respective buttons are pressed by an operator or a service man, various operation instruction signals of the hybrid construction machine 1 are transmitted to the controller 16. As one of the operation button 51a, an operation mode selection button is installed. When the button is pressed by the operator, the optimal operation mode may be set in response to the operation contents among the plurality of operation modes. For example, it is possible to set a “heavy excavating mode (power mode)” capable of maintaining a heavy operation amount (the amount of earth and sand excavated per unit time) or a “fuel consumption saving mode (economy mode)” capable of further suppressing a fuel efficiency during a light load operation. When any operation mode is selected, the output torque (the engine torque) of the engine 12 (see FIG. 3) or the absorption torque (the pump absorption torque) of a hydraulic pump 13 (see FIG. 3) driven by the engine 12 is selected and controlled in response to the operation mode. The selection and the control are performed in a manner such that the engine controller 14 (see FIG. 3) or the controller 16 transmits the control signal to the engine 12 or the hydraulic pump 13, and the engine torque and the pump absorption torque in response to the set operation mode are selected and controlled, where a control is performed so that the engine speed is maintained in the vicinity of the matching point where two torques are equal to each other.

### Internal Configuration

Next, an internal configuration of the hybrid construction machine 1 will be described. FIG. 3 is a block diagram illustrating an internal configuration of the hybrid construction machine 1 illustrated in FIG. 1. In FIG. 3, the controller 16 outputs a revolution instruction value for allowing an engine speed to be a target engine speed n_com to the engine controller 14, and the engine controller 14 increases or decreases the fuel injection amount so that the engine target engine speed n_com may be obtained in a target torque line. Further, the engine controller 14 outputs engine data eng_data including an engine torque estimated from the engine speed and the fuel injection amount of the engine 12 to the controller 16.

The drive shaft of the hydraulic pump 13 is connected to an output shaft of the engine 12, and when the output shaft of the engine rotates, the hydraulic pump 13 is driven. The hydraulic pump 13 is a variable displacement hydraulic pump, and a capacity q (cc/rev) changes by changing an inclination angle of a swash plate. Furthermore, the hydraulic pump 13 may be a double pump or a tandem pump. Further, a PTO shaft 20 is installed between the engine 12 and the hydraulic pump 13 or a generator motor 21, but the output shaft of the engine 12 and the rotor shaft of the generator motor 21 may be coaxially provided, and the rotor shaft of the generator motor 21 and an input shaft of the hydraulic pump 13 may be coaxially provided. That is, the engine 12, the generator motor 21, and the hydraulic pump 13 may be arranged in series. Furthermore, the embodiment may be implemented without using the PTO shaft 20.

The pressure oil which is discharged from the hydraulic pump 13 at a discharge pressure PRp and a flow rate Q (cc/min) is supplied to each of a boom operation valve 31, an arm operation valve 32, a bucket operation valve 33, a right traveling operation valve 35, and a left traveling operation valve 36. The pump discharge pressure PRp is detected by a hydraulic sensor 17, and a hydraulic pressure detection signal is input to the controller 16.

The respective pressure oils discharged from the operation valves 31, 32, 33, 35, and 36 are supplied to the boom cylinder 4a, the arm cylinder 5a, the bucket cylinder 6a, the right traveling motor 8, and the left traveling motor 9, respectively. Accordingly, the boom cylinder 4a, the arm cylinder 5a, the bucket cylinder 6a, the traveling motor 8, and the traveling motor 9 are respectively driven, and the boom 4, the arm 5, the bucket 6, the right and left crawler tracks of the lower traveling body 3 are operated.

The right operation lever 41 for operating the operation unit is an operation lever which operates the boom 4 and the bucket 6, operates the boom 4 and the bucket 6 in response to the operation direction, and operates the boom 4 and the bucket 6 at a speed in response to the operation amount.

The operation lever 41 is provided with a sensor 45 which detects the operation direction and the operation amount. The sensor 45 inputs a lever signal representing the operation direction and the operation amount of the operation lever 41 to the controller 16. In a case where the operation lever 41 is operated in a direction to operate the boom 4, a boom lever signal Lb0 representing a boom raising operation amount and a boom lowering operation amount in response to the operation direction and the operation amount with respect to the neutral position of the operation lever 41 is input to the controller 16. Further, in a case where the operation lever 41 is operated in a direction to operate the bucket 6, a bucket lever signal Lbk representing a bucket excavating operation amount and a bucket dumping operation amount in response to the operation direction and the operation amount with respect to the neutral position of the operation lever 41 is input to the controller 16.

In a case where the operation lever 41 is operated in a direction to operate the boom 4, a pilot pressure (PPC pressure) PRbo in response to the operation amount of the operation lever 41 is added to a pilot port 31a corresponding to the operation direction (the boom raising direction and the boom lowering direction) of the operation lever among the respective pilot ports of the boom operation valve 31.

Similarly, in a case where the operation lever 41 is operated in a direction to operate the bucket 6, a pilot pressure (PPC pressure) PRbk in response to the operation amount of the operation lever 41 is added to a pilot port 33a corresponding to the operation direction (the bucket excavating direction and the bucket dumping direction) of the operation lever among the respective pilot ports of the bucket operation valve 33.

The left operation lever 42 for swing the operation unit is an operation lever which operates the arm 5 and the upper swing body 2, operates the arm 5 and the upper swing body 2 in response to the operation direction, and operates the arm 5 and the upper swing body 2 at a speed corresponding to the operation amount.

The operation lever 42 is provided with a sensor 46 which detects the operation direction and the operation amount. The sensor 46 inputs a lever signal representing the operation direction and the operation amount of the operation lever 42 to the controller 16. In a case where the operation lever 42 is operated in a direction to operate the arm 5, an arm lever signal Lar representing an arm excavating operation amount and the arm dumping operation amount in response to the operation direction and the operation amount with respect to the neutral position of the operation lever 42 is input to the controller 16. Further, in a case where the operation lever 42 is operated in a direction to operate the upper swing body 2, a swing lever signal Lsw representing a right swing operation amount and a left swing operation amount in response to the operation direction and the operation amount with respect to the neutral position of the operation lever 42 is input to the controller 16.

In a case where the operation lever 42 is operated in a direction to operate the arm 5, a pilot pressure (PPC pressure) PRar in response to the operation amount of the operation lever 42 is added to a pilot port 32a corresponding to the operation direction (the arm excavating direction and the arm dumping direction) of the operation lever among the respective pilot ports of the arm operation valve 32.

On the other hand, in a case where the operation lever 42 is operated in a direction to operate the upper swing body 2, the swing lever signal Lsw corresponding to the operation amount (the right swing direction and the left swing direction) of the operation lever 42 is input to the controller 16, and the controller 16 outputs a swing signal SWG_com corresponding to the swing lever signal Lsw to the swing controller 112, so that the swing motor 113 is rotationally driven.

A pilot pressure (PPC pressure) PRcr corresponding to the operation amount of the operation lever 43 is added to a pilot port 35a of the right traveling operation valve 35. Similarly, a pilot pressure (PPC pressure) PRcl corresponding to the operation amount of the operation lever 44 is added to a pilot port 36a of the left traveling operation valve 36.

The pilot pressure PRcr and the pilot pressure PRcl are respectively detected by hydraulic sensors 18 and 19, and are input to the controller 16.

The respective operation valves 31, 32, 33, 35, and 36 are flow rate direction control valves, move spools in a direction corresponding to the operations directions of the corresponding operation levers 41 to 44, and move the spools so that oil passageways are opened by the opening areas corresponding to the operation amounts of the operation levers 41 to 44.

A pump control valve 15 is operated by a control current pc-epc output from the controller 6, and the pump control valve 5 is operated through a servo piston.

The pump control valve 15 controls the inclination angle of the swash plate of the hydraulic pump 13 so that the product of the discharge pressure PRp (kg/cm²) of the hydraulic pump 13 and the capacity q (cc/rev) of the hydraulic pump 13 does not exceed a pump absorption torque Tpcom corresponding to the control current pc-epc. This control is called a PC control.

The lock lever 26 is a lever which operates a switching valve 26a installed between the hydraulic pump 13 and each of the operation valves 31, 32, 33, 35, and 36, and when the lock lever 26 is operated, a lock state may be enabled in which the transmission of the oil pressure from the hydraulic pump 13 to each of the operation valves 31, 32, 33, 35, and 36 is shut off. In the lock state, the discharge pressure PRp detected by the hydraulic sensor 17 becomes zero and even when the operation levers 41 and 42 and the traveling levers 43 and 44 move, the hydraulic actuator such as the boom cylinder 4a is not operated in response to the operation amount.

The controller 16 outputs a rotation instruction value to the engine controller 14 including the governor, and adjusts the engine speed n and the torque T of the engine 12 by increasing or decreasing the fuel injection amount so as to obtain the engine target engine speed corresponding to the load of the current hydraulic pump 13.

On the other hand, the output shaft of the engine 12 is connected to the driving shaft of the hydraulic pump 13 and the driving shaft of the generator motor 21 through the PTO shaft 20. The generator motor 21 performs a power generating action and an electrical actuation. That is, the generator motor 21 is operated as electrical machine (a motor), and is also operated as a generator. Further, the generator motor 21 also serves as a starter which starts the engine 12. When the starter switch is turned on, the generator motor 21 performs an electrical actuation, so that the output shaft of the engine 12 is rotated at a low rotation speed (for example, 400 to 500 rpm) and the engine 12 is started. The engine 12 may be started by an alternator using the starter switch.

The torque of the generator motor 21 is controlled by the inverter function inside a generator motor controller 110. The inverter function controls the torque of the generator motor 21 in response to a generator motor instruction value GEN_com output from the controller 16.

The generator motor controller 110 is electrically connected to a capacitor 22 that is an electricity storage device through a DC power line. Furthermore, the power supply of the controller 16 may be the capacitor 22 or the other electricity storage device (not illustrated).

The capacitor 22 accumulates (charges) the electrical power generated when the generator motor 21 performs a power generating action. Further, the capacitor 22 supplies the electrical power in which charge as capacitance is accumulated to the generator motor controller 110. Furthermore, the capacitor 22 (for example, an electrical double layer capacitor) is an example of the electricity storage device, and examples of the electricity storage device include a lead battery, a nickel hydride battery, and a lithium ion battery other than the capacitor.

The generator motor 21 is provided with a rotation sensor 24 which detects the current actual engine speed GEN_spd (rpm) of the generator motor 21, that is, the actual engine speed of the engine 12. A signal representing the actual engine speed GEN_spd detected by the rotation sensor 24 is input to the controller 16.

Further, the capacitor 22 is equipped with a voltage sensor 25 which detects a voltage BATT_volt of the capacitor 22. A signal representing the voltage BATT_volt detected by the voltage sensor 25 is input to the controller 16. Further, the capacitor 22 is equipped with a temperature sensor 22a which detects the temperature of the capacitor 22. The value detected by the temperature sensor 22a is input to the controller 16.

Further, the controller 16 outputs the generator motor instruction value GEN_com to the generator motor controller 110, and performs a power generating action or an electrical actuation of the generator motor 21. When the instruction value GEN_com for allowing the generator motor 21 to be operated as a generator is output from the controller 16 to the generator motor controller 110, a part of the output torque generated by the engine 12 is transmitted to the driving shaft of the generator motor 21 through the PTO shaft 20 and power is generated by absorbing the torque of the engine 12. Then, AC power generated by the generator motor 21 is converted into DC power by the generator motor controller 110, and the power is accumulated (charged) in the capacitor 22 through a DC power line.

Further, when the generator motor instruction value GEN_com for allowing the generator motor 21 to be operated as an electrical motor is output from the controller 16 to the generator motor controller 110, the generator motor controller 110 performs control so that the generator motor 21 is operated as an electrical motor. That is, the electrical power accumulated in the capacitor 22 is converted into AC electrical power by the generator motor controller 110, and is supplied to the generator motor 21 so as to rotate the drive shaft of the generator motor 21. Accordingly, a torque is generated by the generator motor 21, and the torque is transmitted to the PTO shaft 20 through the drive shaft of the generator motor 21, so that the torque is added to the output torque of the engine 12 (the output of the engine 12 is assisted). The added output torque is absorbed to the hydraulic pump 13. Furthermore, in FIG. 2, the PTO shaft 20 is installed between the engine 12 and the hydraulic pump 13 or the generator motor 21, but the output shaft of the engine 12 and the rotor shaft of the generator motor 21 may be coaxially provided and the rotor shaft of the generator motor 21 and the input shaft of the hydraulic pump 13 may be coaxially provided. That is, the engine 12, the generator motor 21, and the hydraulic pump 13 may be arranged in series. Furthermore, the embodiment may be implemented without using the PTO shaft 20.

The power generating amount (the absorbed torque amount) and the electrical actuation amount (the assist amount; the generated torque amount) of the generator motor 21 change in response to the contents of the generator motor instruction value GEN_com.

The controller 16 calculates the target engine speed Ngen_com of the generator motor 21 corresponding to the current engine target engine speed n_com by the following equation.

Ngen_com=n_com×K2

Here, K2 is a speed reduction ratio of the PTO shaft 20.

The generator motor controller 110 performs the engine speed control or the torque control of the generator motor 21. Here, the engine speed control indicates a control in which the engine speed of the generator motor 21 is adjusted so as to obtain the target engine speed by giving the target engine speed as the generator motor instruction value GEN_com. Further, the torque control indicates a control in which the torque of the generator motor 21 is adjusted so that the target torque is obtained by giving the target torque as the generator motor instruction value GEN_com.

In a case where the controller 16 performs the engine speed control, when a difference between the engine target engine speed and the actual engine speed of the engine 12 becomes a predetermined threshold value or more, assist control is performed by sending a generator motor instruction value GEN_com for assisting the engine 12 by the generator motor 21 to the generator motor controller 110.

In a case where the assisting of the generator motor 21 is performed, the engine 12 is accelerated. In this case, since there is the assisting of the generator motor 21, the absorption torque of the hydraulic pump 13 increases at the initial step of increasing the rotation of the engine compared to a case without any assisting. For this reason, the operation unit moves fast with respect to the movement of the operation lever, and degradation in the operation efficiency may be suppressed, thereby reducing an unpleasant operation sensation given to an operator.

On the other hand, the hybrid construction machine 1 is configured to swing the upper swing body 2 by the electric actuator as described above. That is, the drive shaft of the swing machinery 114 is connected to the swing motor 113 as the electric motor, and when the swing motor 113 is driven, the swing machinery 114 is driven and the upper swing body 2 is swung through the swing pinion, the swing circle, and the like.

The swing motor 113 performs a power generating action and an electrical actuation. That is, the swing motor 113 is operated as an electrical motor, and is also operated as a generator. When the swing motor 113 is operated as an electrical motor, the upper swing body 2 swings. When the swing operation of the upper swing body 2 stops, the torque of the upper swing body 2 is absorbed and the swing motor 113 is operated as a generator.

The driving of the swing motor 113 is controlled by the swing controller 112. The swing controller 112 is electrically connected to the capacitor 22 through the DC power line, and is electrically connected to the generator motor 21 through the generator motor controller 110. The swing controller 112 and the generator motor controller 110 are controlled in response to the instruction output from the controller 16.

The current supplied to the swing motor 113, that is, the swing load current SWG_curr representing the load of the upper swing body 2 is detected by a current sensor 111. The swing load current SWG_curr detected by the current sensor 111 is input to the controller 16. Here, as for a swing motor lock button 61 illustrated in FIG. 3, when the button is pressed, the supply of the current to the swing motor 113 is electrically interrupted. When the operator presses the swing motor lock button 61, the upper swing body 2 may not rotate even when the left operation lever 42 for the swing operation is operated.

### Capacitor Capacitance Measurement Process

Before performing the measurement of the capacitance of the capacitor, a process of releasing (discharging) charges accumulated in the capacitor 22 is performed. The charge releasing does not need to be essentially performed, but it is desirable to perform the charge releasing so as to prevent any problem in comparison in a case where the measurement of the capacitance of the capacitor is performed at different date and time.

In the charge releasing process, first, the generator motor controller 110 performs a rated fixed current control on the generator motor 21, and performs a rated fixed voltage control on a booster (not illustrated).

The generator motor controller 110 continues the rated fixed voltage control while a capacitor voltage Vcap is higher than the first voltage V1. It is desirable that the value of the first voltage V1 is set to the minimum value in the voltage change range in the standard operation of the capacitor 22.

When the generator motor controller 110 continues the rated fixed voltage control, the capacitor voltage Vcap starts to decrease from an initial value Vcap0 in time. In contrast, a booster output voltage Vcnv remains as the initial value Vcnv0 during the rated fixed voltage control.

Subsequently, when the capacitor voltage Vcap decreases to the first voltage V1, the generator motor controller 110 changes the control contents. Specifically, the generator motor controller 110 performs the rated fixed current control on the generator motor 22, and performs a voltage control in which a predetermined ratio between the booster output voltage Vcnv and the capacitor voltage Vcap is maintained on the booster. After the capacitor voltage reaches the first voltage V1, the booster output voltage Vcnv gradually decreases while maintaining the constant ratio (Vcnv/Vcap) with respect to the capacitor voltage Vcap. For example, the ratio is set to a value in which the inductor inside the booster is not saturated and the loss of the booster becomes minimal. Subsequently, when the capacitor voltage Vcap decreases to the third voltage V3, the generator motor controller 110 stops the control.

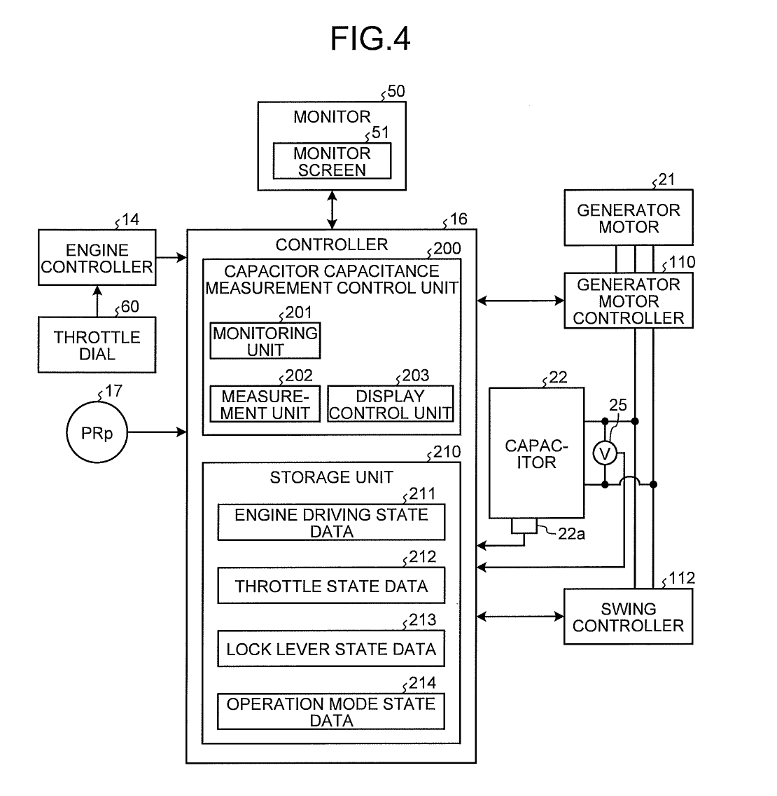

Next, the capacitor capacitance measurement process by the controller 16 will be described. FIG. 4 is a block diagram illustrating a device configuration or the like involved with the measurement of the capacitance of the capacitor of the controller 16 illustrated in FIG. 3. As illustrated in FIG. 4, the controller 16 includes a capacitor capacitance measurement control unit 200 and a storage unit 210. The capacitor capacitance measurement control unit 200 includes a monitoring unit 201, a measurement unit 202 which performs a capacitor capacitance measurement process, and a display control unit 203 which controls the display involved with the capacitor capacitance measurement process on the monitor 50. Further, when the throttle dial 60 is operated by the operator or the service man, the electric signal according to the operation amount (rotation amount) of the throttle dial 60 is transmitted to the engine controller 14.

The monitoring unit 201 performs a process of determining whether four conditions for performing the measurement of the capacitance of the capacitor are all satisfied, that is,

Condition 1: the engine 12 needs to be driven.

Condition 2: the throttle dial 60 needs to be maximally set.

Condition 3: the lock lever 26 needs to be positioned at the lock state (including the lock state according to the operation of the swing motor lock button 61).

Condition 4: the operation mode needs to be selected and set as the power mode.

The monitoring unit 201 transmits a control signal for starting or continuing the measurement of the capacitance of the capacitor to the measurement unit 202. Here, the reason why Conditions 2 and 4 are set is because the engine 12 may be driven at the stable engine speed and the generator motor 21 may be also rotated at the stable engine speed by maximally setting the throttle dial 60 and selecting the power mode as the operation mode. That is, the generator motor 21 may perform the stable power generating action and the stable and accurate measurement of the capacitance of the capacitor. Further, the reason why condition 3 is set is because it is assumed that the service man or the operator moves from the driver seat 70 during the measurement of the capacitance of the capacitor. At this time, when the lock lever 26 is not locked, a part of the body of the service man may come into contact with the operation lever. The setting prevents an inaccurate measurement of the capacitance of the capacitor with a change in the output of the engine 12 due to the movement of the operation lever. Further, the monitoring unit 201 sets whether four conditions of Conditions 1 to 4 are all satisfied as the determination reference for starting or continuing the measurement of the capacitance of the capacitor. However, even when only Conditions 1 to 3 are satisfied except for Condition 4, the capacitance of the capacitor may be stably and accurately measured. For example, the operation mode is set as the economy mode instead of the power mode. Since the hybrid construction machine 1 is controlled by the controller 16 and the engine controller 14 so that the engine 12 is driven at the constant engine speed even in the economy mode, Condition 4 is not an essential condition for determining whether the capacitance of the capacitor is stably and accurately measured. Furthermore, the driving of the engine 12 in Condition 1 is essentially needed in the measurement of the capacitance of the capacitor, but is not essentially needed for the satisfaction of the condition.

The storage unit 210 stores engine driving state data 211, throttle state data 212, lock lever state data 213, and operation mode state data 214, and the monitoring unit 201 determines whether Conditions 1 to 4 described above are satisfied by referring to the respective stored state data items stored therein. The engine driving state data 211 stores the engine speed in the engine data eng_data transmitted from the engine controller 14, and the monitoring unit 201 determines that Condition 1 is satisfied when the engine speed is a predetermined value or more. The engine speed may be detected by using a rotation sensor or the like which is attached to the engine 12. The throttle state data 212 stores the throttle dial value (the data obtained by changing an electric signal as a numerical value) of the throttle dial 60, and the monitoring unit 201 determines that Condition 2 is satisfied when the throttle dial value becomes a maximum value. The lock lever state data 213 stores the discharge pressure PRp, and it is determined that Condition 3 is satisfied when the data of the discharge pressure PRp is zero. Furthermore, the position of the lock lever 26 may be detected by a position detecting sensor such as a limit switch, and the detection signal may be stored in the lock lever state data 213. The operation mode state data 214 stores the operation mode instructed from the monitor 50, and it is determined that Condition 4 is satisfied when the operation mode is the power mode.

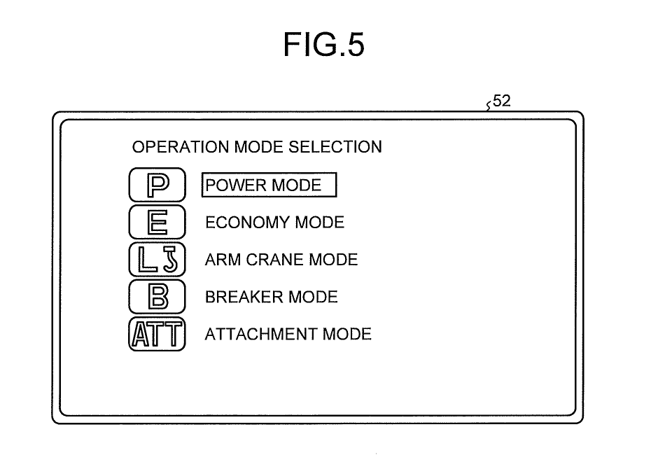

Furthermore, the selection of the operation mode using the monitor 50 is performed in a manner such that an operation mode selection display screen 52 illustrated in FIG. 5 is displayed on the monitor screen 51 and the mode is selected by using the operation mode selection display screen 52. Here, the operation mode includes a P-mode (a power mode), an E-mode (an economy mode), an L-mode (an arm crane mode: a cargo hoisting mode), a B-mode (a breaker mode), an ATT mode (an attachment mode), and the like. The P-mode or the E-mode is a mode when a general excavating operation or the like is performed, and in the E-mode, the maximum output of the engine is suppressed compared to the P-mode. The L-mode is a minute operation mode in which the construction machine moves slow by suppressing the engine speed (at the medium speed) as in the arm crane operation in which a cargo hung on the hook is lifted. The B-mode is a mode in which an operation is performed by attaching a breaker for breaking a rock as an attachment, and is a mode in which the operation is performed by setting the engine speed to the medium high speed. The ATT mode is a mode in which an operation is performed while the engine speed is set from the medium speed to the high speed, and is a preliminary mode in which a specific attachment such as a grapple is attached.

### Display Control Process

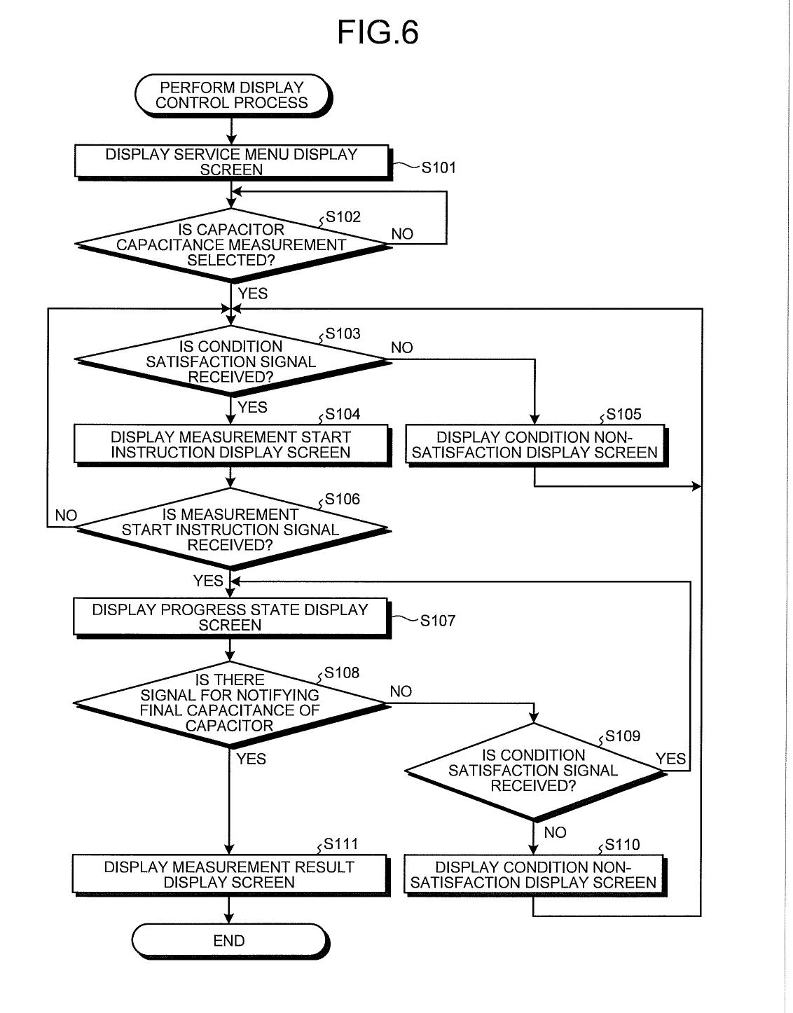

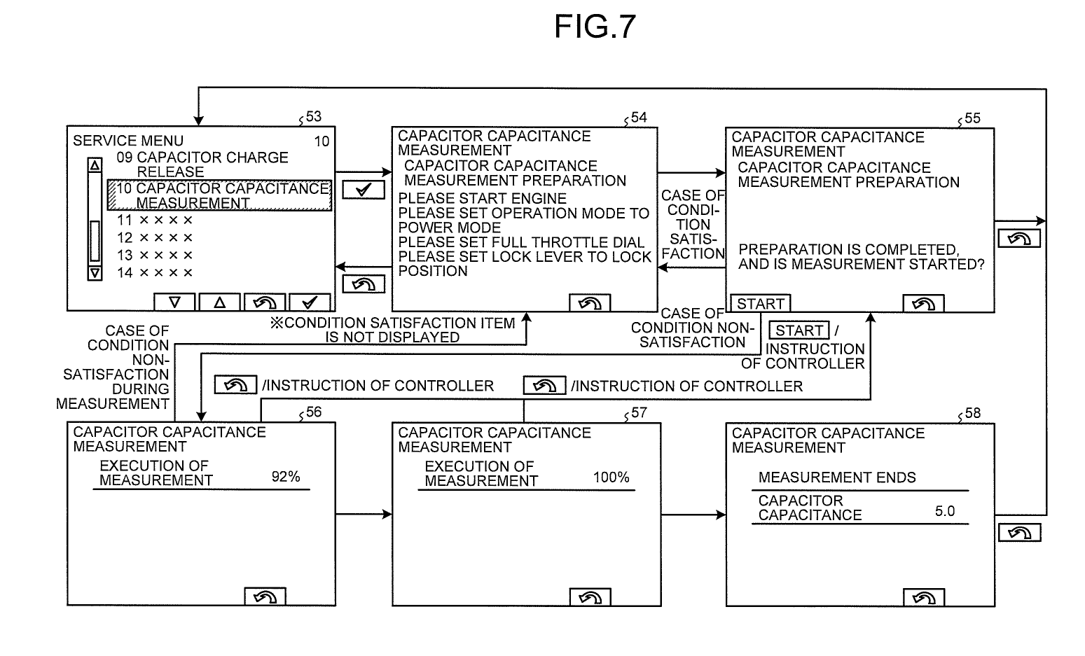

FIG. 6 is a flowchart illustrating a display control process procedure according to the display control unit 203. Further, FIG. 7 is a diagram illustrating a transition of a screen display state of the monitor screen 51 by the display control unit 203. In FIGS. 6 and 7, the display control unit 203 first displays a service menu display screen 53 on the monitor screen 51 (step S101). The service menu display screen 53 is a failure diagnosis screen which is displayed by the service man who inputs an ID or a password by operating the operation button 51a from a main menu screen (not illustrated). Here, a case is assumed in which the capacitance of the capacitor is measured by the service man, but the capacitance of the capacitor may be also measured by the manager of the hybrid construction machine 1 or the manager of a company that rents the hybrid construction machine 1, as needed. That is, the measurement is not limited by the specific service man. Further, the service menu display screen 53 may be displayed by the specific operation of the operation button 51a (for example, the operation of simultaneously pressing the plurality of operation buttons) instead of the input of the ID or the password. Further, a system may be adopted in which the service menu display screen 53 is displayed by using the ID key of the immobilizer instead of the input of the ID or the password. The service menu display screen includes the selection items of the capacitor charge releasing, the capacitor capacitance measurement, and the like.

Here, a cursor is moved by the operation of the operation button 51a, and the operation button 51a corresponding to the check button “Re (tick mark)” of the service menu display screen 53 is pressed, thereby determining whether the item of the capacitor capacitance measurement is selected (step S102). When the item of the capacitor capacitance measurement is selected (Yes in step S102), it is determined whether a condition satisfaction signal representing that all conditions of Conditions 1 to 4 are satisfied is received from the monitoring unit 201 (step S103). When the condition satisfaction signal is received (Yes in step S103), a measurement start instruction display screen 55 is displayed (step S104) and the routine proceeds to step S106. When the condition satisfaction signal is not received (No in step S103), a condition non-satisfaction display screen 54 is displayed (step S105) and the routine proceeds to step S103. At this time, the condition non-satisfaction display screen 54 displays the condition items which are not satisfied and does not display the condition items which are satisfied. Then, guidance contents for asking the satisfaction of the condition items which are not satisfied is displayed on the condition non-satisfaction display screen 54. On the other hand, the measurement start instruction display screen 55 displays the measurement enabled state and the measurement start instruction button “START”. When the operation button 51a corresponding to the measurement start instruction button “START” is pressed, the measurement of the capacitance of the capacitor starts. Accordingly, when Conditions 1 to 4 are not satisfied, the measurement of the capacitance of the capacitor may not be started by pressing the measurement start instruction button “START”.

Subsequently, the display control unit 203 determines whether a measurement start instruction signal is received by the pressing of the operation button 51a corresponding to the measurement start instruction button “START” (step S106). When the measurement start instruction signal is received (Yes in step S106), the measurement of the capacitance of the capacitor by the measurement unit 202 is started, but the measurement unit 202 specifically calculates the ratio of the elapsed time with respect to the entire time necessary for the measurement of the capacitance of the capacitor. The entire time necessary for the measurement of the capacitance of the capacitor is stored in advance in a storage unit (not illustrated) inside the controller 16. When progress state display screens 56 and 57 representing the progress state of the measurement of the capacitance of the capacitor are displayed (step S107) and the measurement start instruction is not present (No in step S106), the routine proceeds to step S103 and the process before the start of the measurement is repeated. The progress state display screens 56 and 57 may display the ratio (%) of the elapsed time by setting the entire time necessary for the measurement of the capacitance of the capacitor as 100% and may visually display the progress state of the measurement of the capacitance of the capacitor to the service man by the display of a bar or a clock according to the graphic display. As illustrated in the progress state display screen 57 of FIG. 7, when the measurement of the capacitance of the capacitor ends, the progress state which is displayed at the right side of the character during the measurement is displayed as 100% and this screen is maintained for several seconds. In this case, the end of the measurement may be notified to the service man by generating a buzzer sound along with the display. Furthermore, the case in which the measurement start instruction is not present indicates a case in which the operation button 51a corresponding to the measurement start instruction button “START” is not pressed for a predetermined time or a case in which the specific operation button 51a is pressed. Furthermore, the progress state of the measurement of the capacitance of the capacitor may display the progress state of the measurement of the capacitance of the capacitor which is calculated for each charging operation to be described below, and plural times of the measurement of the capacitance of the capacitor may be displayed as the progress state in the entire time necessary for the measurement of the capacitance of the capacitor.

Subsequently, the display control unit 203 performs a process of determining whether a signal for notifying the final capacitance of the capacitor is received from the measurement unit 202, that is, the measurement of the capacitance of the capacitor ends (step S108). When the signal for notifying the final capacitance of the capacitor is received (Yes in step S108), the progress state display screen 57 is switched to a measurement result display screen 58 representing the measurement result (step S111), and the display control process ends. On the other hand, when the signal for notifying the final capacitance of the capacitor is not received (No in step S108), it is determined whether the condition satisfaction signal is received from the monitoring unit 201 (step S109). When the condition satisfaction signal is received (Yes in step S109), the routine proceeds to step S107 and the progress state display screens 56 and 57 are updated and displayed. When the condition satisfaction signal is not received (No in step S109), the routine proceeds to the condition non-satisfaction display screen 54, the non-satisfaction condition is displayed (step S110), and the routine proceeds to step S103 so as to return to the process before the start of the measurement of the capacitance of the capacitor. As described above, when at least one of Conditions 1 to 4 is not satisfied during the measurement of the capacitance of the capacitor, the measurement of the capacitance of the capacitor is not accurately performed. Accordingly, a process is performed which prompts the re-measurement operation of the service man by stopping the measurement.

Furthermore, the temperature during the measurement of the capacitance of the capacitor may be detected by attaching a temperature sensor 26a such as a thermistor to the casing of the capacitor 22 or a capacitor cell constituting the capacitor 22. The measurement result display screen 58 displays a value in which the value of the final capacitance of the capacitor is corrected in temperature when the value of the temperature sensor 26a is 0° C. or less or the value of the temperature sensor 26a exceeds 25° C.

Further, when the operation button 51a corresponding to the return button is pressed on the progress state display screens 56 and 57, the measurement start instruction display screen 55 before the measurement may be compulsorily displayed. That is, when the operation button 51a is pressed, a measurement stop signal is transmitted from the monitor 50 to the controller 16, and the controller 16 transmits a control signal for driving the engine 12 at the idling engine speed to the engine controller 14, whereby the measurement may be compulsorily stopped.

### Monitoring Process

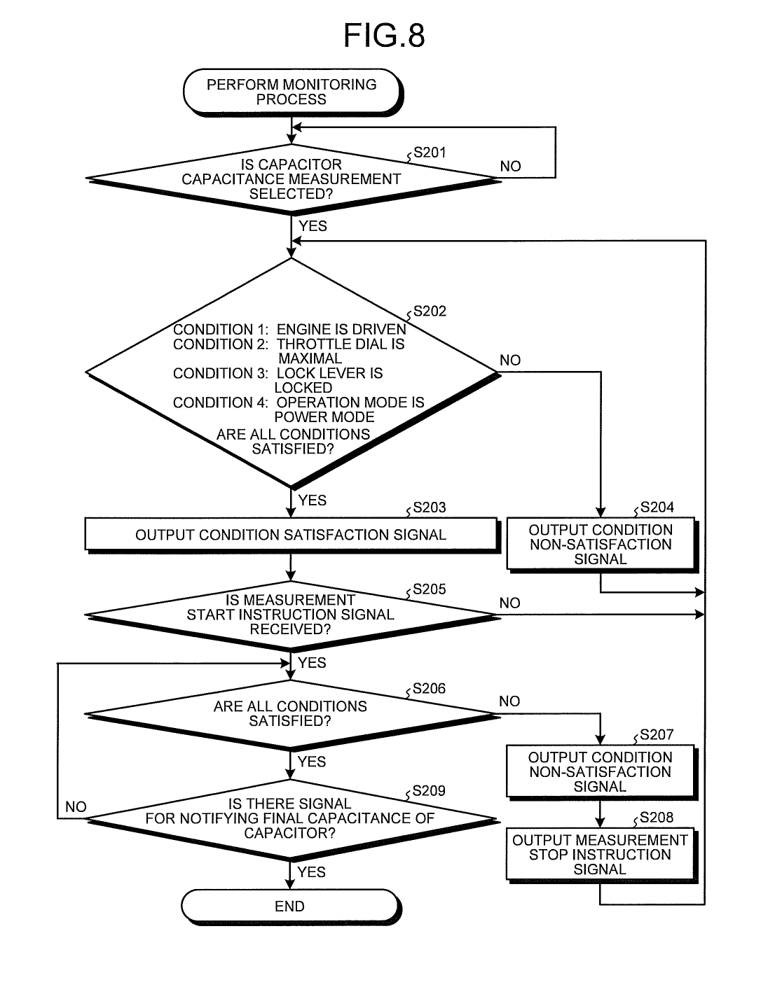

FIG. 8 is a flowchart illustrating a monitoring process procedure by the monitoring unit 201. In FIG. 8, the monitoring unit 201 determines whether a signal representing the selection of the items of the measurement of the capacitance of the capacitor is received from the display control unit 203 (step S201). When the signal representing the selection of the items of the measurement of the capacitance of the capacitor is received (Yes in step S201), it is determined whether Conditions 1 to 4 are all satisfied by referring to the storage unit 210 (step S202). When Conditions 1 to 4 are all satisfied (Yes in step S202), a condition satisfaction signal representing the current state is generated, the signal is output to the measurement unit 202 and the display control unit 203 (step S203), and then the routine proceeds to step 205. On the other hand, when Conditions 1 to 4 are all not satisfied (No in step S202), a condition non-satisfaction signal including the non-satisfaction item or the satisfaction item and representing the condition non-satisfaction state is output to the measurement unit 202 and the display control unit 203 (step S204), and the determination process of step S202 is repeated.

Subsequently, the monitoring unit 201 determines whether a measurement start instruction signal is received from the display control unit 203 (step S205). When the measurement start instruction signal is received (Yes in step S205), it is determined whether Conditions 1 to 4 are all satisfied as in step S202 (step S206). On the other hand, when the measurement start instruction signal is not received (No in step S205), the routine returns to step S202, so that it becomes the state before the measurement.

When all conditions are satisfied in step S206 (Yes in step S206), it is determined whether a signal for notifying the final capacitance of the capacitor is received from the measurement unit 202 (step S209). Then, when the signal for notifying the final capacitance of the capacitor is received (Yes in step S209), the monitoring process ends. When the signal for notifying the final capacitance of the capacitor is not received (No in step S209), since the capacitance of the capacitor is being measured, the routine proceeds to step S206 so as to repeat the process of step 206. On the other hand, when all conditions are not satisfied in step 206 (No in step S206), a condition non-satisfaction signal is output (step S207), a capacitor capacitance measurement stop instruction signal is output to the measurement unit 202 (step S208), and the routine returns to step S202.

Since the monitoring unit 201 performs the above-described monitoring process, the capacitance of the capacitor may be measured while Conditions 1 to 4 are satisfied. Also, since the satisfaction state of Conditions 1 to 4 is monitored even during the measurement of the capacitance of the capacitor, the capacitance of the capacitor may be stably and accurately measured.

### Measurement Process

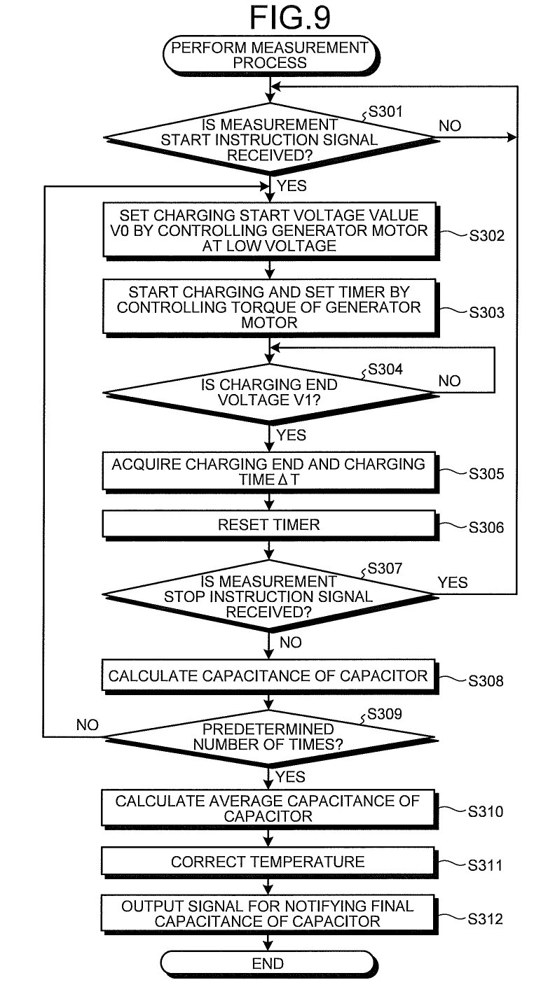

FIG. 9 is a flowchart illustrating a procedure of a capacitor capacitance measurement process by the measurement unit 202. Furthermore, the capacitor capacitance measurement process by the measurement unit 202 is performed on the assumption that the charge releasing process of the capacitor is performed in advance. As described above, the capacitor charge releasing does not need to be essentially performed, but it is desirable to perform the charge releasing so as to prevent any problem in comparison in a case where the measurement of the capacitance of the capacitor is performed at different date and time. In FIG. 9, the measurement unit 202 first determines whether the measurement start instruction signal is received from the display control unit 203 (step S301). Then, only for the case where the measurement start instruction signal is received (Yes in step S301), the fixed voltage control of the generator motor 21 is performed and the voltage value of the capacitor 22 is set to a charging start voltage value V0 (step S302). Subsequently, the torque control of the generator motor 21 is performed, so that the charging of the capacitor 22 is started and a timer (not illustrated) is set (step S303).

In order to detect the state of the capacitor 22 as a voltage, the voltage sensor 25 is electrically connected to the capacitor 22. The measurement unit 202 receives a signal specifically representing the voltage value from the voltage sensor 25. Subsequently, it is determined whether the voltage value of the capacitor 22 becomes a predetermined charging end voltage value V1 (step S304). Then, only for the case of the charging end voltage value V1 (Yes in step S304), the charging of the capacitor 22 ends, and the data of the charging time AT from the start of the charging is acquired from the timer (step S305). Then, the measurement unit 202 resets the timer (step S306).

Subsequently, it is determined whether the measurement stop instruction signal is received from the monitoring unit 201 (step S307). When the measurement stop instruction signal is received (Yes in step S307), the routine returns to step S301 so as to wait for the receiving of the measurement start instruction signal. On the other hand, when the measurement stop instruction signal is not received (No in step S307), the measurement process is continued and the capacitance of the capacitor is calculated (step S308).

The calculation of the capacitance of the capacitor is performed based on the engine speed value Ne and the torque value Tr of the generator motor 21, the charging start voltage value VO and the charging end voltage value V1, and the charging time ΔT. The engine speed value Ne is detected by the rotation sensor 24 which is attached to the generator motor 21, and the torque value Tr is detected by a torque sensor (not illustrated) attached to the generator motor 21. Further, the charging start voltage value V0 and the charging end voltage value V1 are detected by the voltage sensor 25 which is electrically connected to the capacitor 22 as illustrated in FIG. 4. A generated energy ΔW of the generator motor 21 is supplied as a charged energy ΔJ of the capacitor 22. The generated energy ΔW may be obtained by using the engine speed value Ne and the torque value Tr of the generator motor 21. That is, the generated energy ΔW may be obtained by the multiplication of the engine speed value Ne and the torque value Tr. Then, when the energy efficiency upon supplying energy from the generator motor 21 to the generator motor controller 110 is denoted by α and the inverter efficiency in the generator motor controller 110 is denoted by β, the charged energy ΔJ of the capacitor 22 is expressed by the following equation (1).

ΔJ=ΔW×α−(β×ΔT) (1)

On the other hand, the charged energy ΔJ of the capacitor 22 is expressed by the following equation (2) using a capacitance C of the capacitor 22 and the charging start voltage value V0 and the charging end voltage value V1 of the capacitor 22.

ΔJ=(½)·C·(V1−V0) (2)

Then, when Equations (1) and (2) are used, the capacitance C of the capacitor 22 may be calculated.

The measurement and the calculation of the capacitance C of the capacitor 22 are performed plural times. This is because the capacitance of the capacitor is further accurately measured by performing the measurement plural times in consideration of a variation in the measurement result. The measurement unit 202 performs the measurement and the calculation of the capacitance of the capacitor plural times by plural charging operations, but the measurement unit 202 determines whether the measurement of the capacitance of the capacitor is performed a predetermined number of times (for example, 10 times) (step S309). When the measurement of the capacitance of the capacitor is not performed a predetermined number of times (No in step S309), the routine returns to step S302, and the measurement of the capacitance of the capacitor is repeatedly performed until the predetermined number of times of the measurement of the capacitance of the capacitor ends (step S302 to step S309). When the measurement of the capacitance of the capacitor is performed a predetermined number of times (Yes in step S309), the average capacitance of the capacitor is calculated (step S310). That is, a calculation for obtaining the value of the average capacitance of the capacitor measured a predetermined number of times is performed. Further, the average capacitance of the capacitor is corrected in temperature based on a capacitor temperature tc detected by the temperature sensor 22a (step S311).

The correction in temperature is performed by using the relation between the capacitor temperature tc and a correction coefficient K. The correction is performed in a manner such that the correction coefficient K corresponding to the capacitor temperature tc detected by the temperature sensor 22a is obtained and the correction coefficient K is multiplied by the average capacitance of the capacitor. The relation between the capacitor temperature tc and the correction coefficient K is, for example, as below.

capacitor temperature tc→correction coefficient K

0° C.→1.03

25° C.→1.00

40° C.→0.99

60° C.→0.98

Furthermore, the correction coefficient K is stored in a predetermined storage unit (memory) of the controller 16, and the correction coefficient K with respect to the capacitor temperature tc is not limited to the representative example. For example, the accurate average capacitance of the capacitor may be obtained in a manner such that the correction coefficient K with respect to the assumed capacitor temperature tc is stored in advance as table data in the storage unit and the correction coefficient K corresponding to the detected capacitor temperature tc is read out from the storage unit. For example, when the capacitor temperature tc is detected as a normal temperature (25° C.), the display control unit 203 displays the value of the average capacitance of the capacitor on the measurement result display screen 58 of FIG. 7, and when the capacitor temperature tc is detected as a low temperature (0° C.), the average capacitance of the capacitor is multiplied by 1.03 as the correction coefficient K and the value of the calculation result is displayed on the measurement result display screen 58.

Subsequently, the measurement unit 202 generates and outputs a signal for notifying the average capacitance of the capacitor corrected in temperature as the final capacitance of the capacitor (step S312), and ends the measurement process.

Furthermore, in the above-described embodiment, the lock state of the lock lever 26 is prepared as one condition, but not only the hydraulic lock but also the electric lock through the operation of the electromagnetic switch by the controller 16 may be performed. This is because the operation lever may be configured as an electric lever. That is, the electric lock state may be realized by using an electric circuit which does not output an electric signal (for example, a voltage) corresponding to the operation even when the electric lever is operated. Further, when the operation of the operation unit or the like is locked by using the electric switch as in the swing motor lock button 61 illustrated in FIG. 2, the swing motor lock button 61 may be set as Condition 3.

Furthermore, the measurement unit 202 determines whether the measurement stops whenever the timer is reset, that is, each measurement ends, but the invention is not limited thereto. When the measurement stop instruction signal is received from the monitoring unit 201, a measurement stop interruption process may be performed in the process of the measurement unit 202.

Further, the display control unit 203 is installed inside the controller 16, but the invention is not limited thereto. For example, the display control unit 203 may be provided in the monitor 50.

Furthermore, as Condition 2 described above, the throttle dial 60 is maximally set, but the adjustment value may be a predetermined value instead of a maximum value.

Further, in the above-described embodiment, the measurement of the capacitance of the electricity storage device is desirably performed on the assumption that the capacitor charge releasing process of the electricity storage device is performed. However, the monitoring unit 201 may set a condition in which the capacitor charge releasing process is performed before starting the measurement of the capacitance of the capacitor of the measurement unit 202, and may start the measurement of the capacitance of the capacitor when all conditions including this condition are satisfied. In this case, the display control unit 203 may further display a condition in which the capacitor charge releasing process is performed when starting the measurement of the capacitance of the capacitor on the condition non-satisfaction display screen 54 as in Conditions 1 to 4. Accordingly, the capacitance of the capacitor may be further accurately measured.

Further, the hybrid construction machine 1 described above is configured to swing the upper swing body 2 by the electric actuator using the electric energy accumulated in the capacitor 22, but the invention is not limited thereto. The upper swing body 2 may be swung by using a hydraulic motor.

### REFERENCE SIGNS LIST

1 hybrid construction machine

2 upper swing body

3 lower traveling body

4 boom

4a boom cylinder

5 arm

5a arm cylinder

6 bucket

6a bucket cylinder

8, 9 traveling motor

12 engine

13 hydraulic pump

14 engine controller

15 pump control valve

16 controller

17 to 19 hydraulic sensor

20 PTO shaft

21 generator motor

22 capacitor

22a temperature sensor

24 rotation sensor

25 voltage sensor

26 lock lever

26a switching valve

31, 32, 33, 35, 36 operation valve

31a to 36a pilot port

41 to 44 operation lever

45, 46 sensor

50 monitor

51 monitor screen

51a operation button

52 operation mode selection display screen

53 service menu display screen

54 condition non-satisfaction display screen

55 measurement start instruction display screen

56, 57 progress state display screen

58 measurement result display screen

60 throttle dial

61 swing motor lock button

70 driver seat

110 generator motor controller

111 current sensor

112 swing controller

113 swing motor

114 swing machinery

115 swing speed sensor

1. A hybrid construction machine comprising:
a measurement unit configured to measure a capacitance of an electricity storage device; and
a monitoring unit configured to monitor a first condition in which an engine is driven, a second condition in which an adjustment value of a fuel adjusting unit adjusting an amount of fuel supplied to the engine is a predetermined value, and a third condition in which an operation unit and/or an upper swing body are locked and transmit a control signal for starting a measurement of the capacitance of the electricity storage device to the measurement unit when all conditions of the first to third conditions are satisfied.

2. The hybrid construction machine according to claim 1,
wherein in the second condition, the adjustment value of the fuel adjusting unit is a maximum value in a adjustable range.

3. The hybrid construction machine according to claim 1,
wherein the monitoring unit is configured to set a fourth condition in which an operation mode of controlling an engine speed of the engine and a pump absorption torque of a hydraulic pump at a constant state is set, and when all conditions of the first to fourth conditions are satisfied, the monitoring unit is configured to transmit the control signal for starting the measurement of the capacitance of the electricity storage device to the measurement unit.

4. The hybrid construction machine according to claim 3,
wherein the monitoring unit is configured to generate a control signal for stopping the measurement of the capacitance of the electricity storage device when at least one condition of the first to fourth conditions is not satisfied during the measurement of the capacitance of the electricity storage device.

5. The hybrid construction machine according to claim 3, further comprising:
a display unit configured to perform a display and an instruction related to at least the measurement of the capacitance of the electricity storage device; and
a display control unit configured to control the display unit to perform a guide display related to at least the measurement of the capacitance of the electricity storage device.

6. The hybrid construction machine according to claim 5,
wherein the display control unit is configured to switch a screen of the display unit to a screen for instructing a start of the measurement of the capacitance of the electricity storage device when all conditions of the first to fourth conditions are satisfied.

7. The hybrid construction machine according to claim 5,
wherein the display control unit is configured to display a progress state of the measurement of the capacitance of the electricity storage device when the measurement unit measures the capacitance of the electricity storage device.

8. The hybrid construction machine according to claim 1,
wherein the measurement unit is configured to perform the measurement of the capacitance of the electricity storage device on a condition that a charge releasing process of the electricity storage device is performed.

9. A method of measuring a capacitance of an electricity storage device of a hybrid construction machine comprising:
monitoring a first condition in which an engine is driven, a second condition in which an adjustment value of a fuel adjusting unit adjusting an amount of fuel supplied to the engine is a predetermined value, and a third condition in which an operation unit and/or an upper swing body are locked to transmit a control signal for starting a measurement of the capacitance of the electricity storage device when all conditions of the first to third conditions are satisfied; and
measuring the capacitance of the electricity storage device when the control signal for starting the measurement of the capacitance of the electricity storage device is received.

10. The method of measuring the capacitance of the electricity storage device of the hybrid construction machine according to claim 9,
wherein the monitoring includes setting a fourth condition in which an operation mode of controlling an engine speed of the engine and a pump absorption torque of a hydraulic pump at a constant state and transmitting the control signal for starting the measurement of the capacitance of the electricity storage device when all conditions of the first to fourth conditions are satisfied.
